(19) United States
(12) Patent Application Publication
(10) Pub. No.: US 2019/0002694 A1
(43) Pub. Date: Jan. 3, 2019

(54) THERMALLY CONDUCTIVE SILICONE COMPOSITION AND SEMICONDUCTOR DEVICE

(71) Applicant: SHIN-ETSU CHEMICAL CO., LTD., Tokyo (JP)

(72) Inventors: Shota AKIBA, Annaka-shi (JP); Kenichi TSUJI, Annaka-shi (JP)

(73) Assignee: SHIN-ETSU CHEMICAL CO., LTD., Tokyo (JP)

(21) Appl. No.: 16/064,327

(22) PCT Filed: Feb. 22, 2017
(86) PCT No.: PCT/JP2017/006602

§ 371 Date: Jun. 20, 2018

(30) Foreign Application Priority Data
Mar. 18, 2016 (JP) 2016-055133

(51) Int. Cl. C08L 83/04; C08K 3/08; C08K 5/14; H01L 23/373

(52) U.S. Cl. CPC C08L 83/04; C08K 3/08; C08K 5/14; H01L 23/3737; H01L 23/3738; C08L 2203/20; C08K 2201/006; C08K 2201/016; C08K 2201/001; C08K 2201/005; C08K 2003/0812; C08K 2003/0806

(57) ABSTRACT

The composition is a thermally conductive silicone composition containing the following components (A) to (C) and (D). The component (A) is an organopolysiloxane that exhibits a kinetic viscosity of 10 to 100,000 mm²/s at 25° C., and is represented by an average composition formula (1)

R¹ₐSiO_{(4-a)/2} (1)

wherein R¹ represents a hydrogen atom, a hydroxy group or a monovalent hydrocarbon group, and a satisfies 1.8≤a≤2.2. The component (B) is a silver powder having a tap density of not lower than 3.0 g/cm³, a specific surface area of not larger than 2.0 m²/g, and an aspect ratio of 2.0 to 150.0. The component (C) is a thermally conductive filler other than the component (B), having an average particle size of 5 to 100 μm and a thermal conductivity of not lower than 10 W/m° C. The component (D) is a platinum-based catalyst, an organic peroxide and/or a catalyst for condensation reaction.

### TECHNICAL FIELD

The present invention relates to a silicone composition superior in thermal conductivity; and a semiconductor device.

### BACKGROUND ART

Since most electronic parts generate heat while in use, it is required that such heat be eliminated from an electronic part to allow this electronic part to function properly. Especially, in the case of an integrated circuit element such as a CPU used in a personal computer, the amount of heat generation has increased due to a higher frequency of operation, which makes a countermeasure(s) against heat a critical issue.

For these reasons, there have been proposed may methods for releasing such heat. Particularly, as for electronic parts generating large amounts of heat, there has been known a method for releasing heat by interposing a thermally conductive material such a thermally conductive grease and a thermally conductive sheet between, for example, an electronic part and a heat sink.

JP-A-Hei-2-153995 (Patent document 1) discloses a silicone grease composition prepared by adding to a particular organopolysiloxane a spherical hexagonal aluminum nitride powder having a particle size within a given range; JP-A-Hei-3-14873 (Patent document 2) discloses a thermally conductive organosiloxane composition prepared by combining an aluminum nitride powder with a fine particle size and an aluminum nitride powder with a coarse particle size; JP-A-Hei-10-110179 (Patent document 3) discloses a thermally conductive silicone grease prepared by combining an aluminum nitride powder and a zinc oxide powder; JP-A-2000-63872 (Patent document 4) discloses a thermally conductive grease composition employing an aluminum nitride powder surface-treated with organosilane.

The thermal conductivity of aluminum nitride is 70 to 270 W/mK. As a material with a higher thermal conductivity, there can be listed diamond whose thermal conductivity is 900 to 2,000 W/mK. JP-A-2002-30217 (Patent document 5) discloses a thermally conductive silicone composition employing diamond, zinc oxide and a dispersant in a silicone resin.

Further, JP-A-2000-63873 (Patent document 6) and JP-A-2008-222776 (Patent document 7) disclose a thermally conductive grease composition(s) prepared by mixing a metallic aluminum powder into a base oil such as a silicone oil.

Furthermore, there have also been published Japanese Patents No. 3130193 (Patent document 8) and No. 3677671 (Patent document 9) in which a silver powder with a high thermal conductivity is used as a filler.

Although some of the abovementioned thermally conductive greases and thermally conductive materials exhibit a high thermal conductivity, they have a large minimum thickness (BLT) when compressed and a high thermal resistance. Meanwhile, those exhibiting a low thermal resistance have a thin BLT, and may exhibit an impaired thermal resistance after a heat cycle test, which lacks reliability. That is, none of the above thermally conducive materials and thermally conducive greases is satisfactory in terms of dealing with heat release from an integrated circuit element such as a CPU generating heat by a larger amount in recent days.

### PRIOR ART DOCUMENT

### Patent Document

Patent document 1: JP-A-Hei-2-153995

Patent document 2: JP-A-Hei-3-14873

Patent document 3: JP-A-Hei-10-110179

Patent document 4: JP-A-2000-63872

Patent document 5: JP-A-2002-30217

Patent document 6: JP-A-2000-63873

Patent document 7: JP-A-2008-222776

Patent document 8: Japanese Patent No. 3130193

Patent document 9: Japanese Patent No. 3677671

### SUMMARY OF THE INVENTION

### Problem to be Solved by the Invention

Therefore, it is an object of the present invention to provide a thermally conductive silicone composition bringing about a favorable heat dissipation effect.

### Means to Solve the Problem

The inventors diligently conducted a series of studies to achieve the above objectives, and completed the invention as follows. That is, the inventors found that thermal conductivity could be dramatically improved by mixing into a particular organopolysiloxane: a silver powder having a particular tap density and specific surface area; and a conductive filler having a particular particle size.

Specifically, the present invention is to provide the following thermally conductive silicone composition and others.
[1]

A thermally conductive silicone composition comprising:

(A) an organopolysiloxane that exhibits a kinetic viscosity of 10 to 100,000 mm²/s at 25° C., and is represented by the following average composition formula (1)

R¹ₐSiO_{(4-a)/2} (1)

wherein R¹ represents at least one selected from the group consisting of a hydrogen atom, a hydroxy group and a saturated or unsaturated monovalent hydrocarbon group having 1 to 18 carbon atoms, and a satisfies 1.8≤a≤2.2;

(B) a silver powder having a tap density of not lower than 3.0 g/cm³, a specific surface area of not larger than 2.0 m²/g, and an aspect ratio of 2.0 to 150.0, the component (B) being in an amount of 300 to 11,000 parts by mass per 100 parts by mass of the component (A);

(C) a thermally conductive filler other than the component (B), having an average particle size of 5 to 100 μm and a thermal conductivity of not lower than 10 W/m° C., the component (C) being in an amount of 10 to 2,750 parts by mass per 100 parts by mass of the component (A); and

(D) a catalyst selected from the group consisting of a platinum-based catalyst, an organic peroxide and a catalyst for condensation reaction, the component (D) being used in a catalyst amount.

[2]

The thermally conductive silicone composition according to [1], wherein the thermally conductive filler as the component (C) is an aluminum powder having a tap density of 0.5 to 2.6 g/cm³ and a specific surface area of 0.15 to 3.0 m²/g.

[3]

The thermally conductive silicone composition according to [1] or [2], wherein the thermally conductive filler as the component (C) has an aspect ratio of 1.0 to 3.0.

[4]

The thermally conductive silicone composition according to any one of [1] to [3], wherein α/β which is a ratio of a mass α of the silver powder as the component (B) to a mass β of the aluminum powder as the component (C) is 3 to 150.

[5]

The thermally conductive silicone composition according to any one of [1] to [4], wherein the whole or part of the component (A) is: an organopolysiloxane as a component (E) that has at least two silicon atom-bonded alkenyl groups in one molecule; and/or an organohydrogenpolysiloxane as a component (F) that has at least two silicon atom-bonded hydrogen atoms in one molecule.

[6]

The thermally conductive silicone composition according to any one of [1] to [5], further comprising:

(G) an organosilane that is contained in an amount of 0 to 20 parts by mass per 100 parts by mass of the component (A), and is represented by the following general formula (2)

R²_{b}Si(OR³)_{4-b} (2)

wherein R² represents at least one group selected from: a saturated or unsaturated monovalent hydrocarbon group that may have a substituent group(s); an epoxy group; an acrylic group; and a methacrylic group, R³ represents a monovalent hydrocarbon group, and b satisfies 1≤b≤3.
[7]

A semiconductor device comprising a heat-generating electronic part and a heat dissipator with the thermally conductive silicone composition as set forth in any one of [1] to [6] being interposed between the heat-generating electronic part and the heat dissipator.

[8]

A method for producing a semiconductor device, comprising:

heating the thermally conductive silicone composition as set forth in any one of <1> to <6> to 80° C. or higher with a pressure of not lower than 0.01 MPa being applied thereto, with the thermally conductive silicone composition being sandwiched between a heat-generating electronic part and a heat dissipator.

### Effect of the Invention

Since the thermally conductive silicone composition of the present invention has an excellent thermal conductivity, it is suitable for use in a semiconductor device.

### BRIEF DESCRIPTION OF THE DRAWINGS

FIG. 1 is a schematic vertical cross-section showing an example of a semiconductor device of the present invention.

### MODE FOR CARRYING OUT THE INVENTION

A thermally conductive silicone composition of the present invention is described in detail hereunder.

### Component (A):

An organopolysiloxane as a component (A) is an organopolysiloxane represented by the following average composition formula (1)

R¹ₐSiO_{(4-a)/2} (1)

(In the above formula, R¹ represents at least one selected from the group consisting of a hydrogen atom, a hydroxy group and a saturated or unsaturated monovalent hydrocarbon group having 1 to 18 carbon atoms. a satisfies 1.8≤a≤2.2.)

This organopolysiloxane exhibits a kinetic viscosity of 10 to 100,000 mm²/s at 25° C.

In the above formula (1), examples of the saturated or unsaturated monovalent hydrocarbon group having 1 to 18 carbon atoms, as represented by R′, include alkyl groups such as a methyl group, an ethyl group, a propyl group, a hexyl group, an octyl group, a decyl group, a dodecyl group, a tetradecyl group, a hexadecyl group and an octadecyl group; cycloalkyl groups such as a cyclopentyl group and a cyclohexyl group; alkenyl groups such as a vinyl group and an allyl group; aryl groups such as a phenyl group and a tolyl group; aralkyl groups such as 2-phenylethyl group and 2-methyl-2-phenylethyl group; and halogenated hydrocarbon groups such as 3,3,3-trifluoropropyl group, 2-(perfluorobutyl)ethyl group, 2-(perfluorooctyl)ethyl group and p-chlorophenyl group. If using the silicone composition of the invention as a grease, it is preferred that “a” be 1.8 to 2.2, especially preferably 1.9 to 2.1, in terms of a consistency required for a silicone grease composition.

Further, it is required that the organopolysiloxane used in the present invention exhibit a kinetic viscosity of 10 to 100,000 mm²/s at 25° C. Because if such viscosity is lower than 10 mm²/s, a composition containing the organopolysiloxane may easily exhibit oil bleeding; and if such viscosity is higher than 100,000 mm²/s, a composition containing the organopolysiloxane may exhibit a higher viscosity and thereby an impaired workability. Here, it is particularly preferred that such kinetic viscosity of the organopolysiloxane be 30 to 10,000 mm²/s at 25° C. The kinetic viscosity of the organopolysiloxane is a value measured by an Ostwald viscometer at 25° C.

### Components (E) and (F):

It is preferred that the whole or part of the component (A) be: an organopolysiloxane as a component (E) that has at least two silicon atom-bonded alkenyl groups in one molecule; and/or an organohydrogenpolysiloxane as a component (F) that has at least two silicon atom-bonded hydrogen atoms in one molecule.

The organopolysiloxane as the component (E) has on average not less than two silicon atom-bonded alkenyl groups (normally 2 to 50) in one molecule; preferably about 2 to 20, more preferably about 2 to 10 silicon-bonded alkenyl groups in one molecule. Examples of the alkenyl groups contained in the organopolysiloxane as the component (E) include a vinyl group, an allyl group, a butenyl group, a pentenyl group, a hexenyl group and a heptenyl group, among which a vinyl group is preferred. The alkenyl groups in the component (E) may be bonded to the silicon atoms at the molecular chain terminals; and/or bonded to the silicon atoms at non-terminal moieties of the molecular chain.

In the organopolysiloxane as the component (E), examples of a silicon atom-bonded organic group other than an alkenyl group include alkyl groups such as a methyl group, an ethyl group, a propyl group, a butyl group, a pentyl group, a hexyl group and a heptyl group; aryl groups such as a phenyl group, a tolyl group, a xylyl group and a naphthyl group; aralkyl groups such as a benzyl group and a phenethyl group; and halogenated alkyl groups such as a chloromethyl group, 3-chloropropyl group and 3,3,3-trifluoropropyl group, among which a methyl group and a phenyl group are particularly preferred.

Examples of the molecular structure of such component (E) include a linear structure, a partially branched linear structure, a cyclic structure, a branched structure and a three-dimensional network structure. However, it is preferred that the component (E) be a linear diorganopolysiloxane having a main chain essentially composed of repeating diorganosiloxane units (D units), and two molecular chain terminals blocked by triorganosiloxy groups; or a mixture of such linear diorganopolysiloxane and a branched or three-dimensionally networked organopolysiloxane.

The organohydrogenpolysiloxane as the component (F) has, in one molecule, at least two (normally 2 to 300), preferably about 2 to 100 silicon atom-bonded hydrogen atoms (i.e. SiH groups); and may be a resinous substance having any of a linear structure, a branched structure, a cyclic structure or a three-dimensional network structure. The hydrogen atoms in the component (F) may be bonded to the silicon atoms at the molecular chain terminals; and/or bonded to the silicon atoms at non-terminal moieties of the molecular chain.

In the organohydrogenpolysiloxane as the component (F), examples of a silicon atom-bonded organic group include alkyl groups such as a methyl group, an ethyl group, a propyl group, a butyl group, a pentyl group, a hexyl group and a heptyl group; aryl groups such as a phenyl group, a tolyl group, a xylyl group and a naphthyl group; aralkyl groups such as a benzyl group and a phenethyl group; and halogenated alkyl groups such as a chloromethyl group, 3-chloropropyl group and 3,3,3-trifluoropropyl group, among which a methyl group and a phenyl group are particularly preferred.

Further, in addition to the organopolysiloxane as the component (A) and as represented by the average composition formula (1), there may also be used together a hydrolyzable group-containing organopolysiloxane (component (H)) represented by the following general formula (3). It is preferred that such hydrolyzable organopolysiloxane be contained in an amount of 0 to 20% by mass, more preferably 0 to 10% by mass, with respect to the component (A).

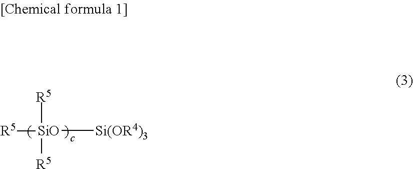

(In the formula (3), R⁴ represents an alkyl group having 1 to 6 carbon atoms; each R⁵ independently represents a saturated or unsaturated, substituted or unsubstituted monovalent hydrocarbon group having 1 to 18 carbon atoms; and c represents 5 to 120.)

The organopolysiloxane represented by the formula (3) assists in highly filling the silicone composition with a powder. Further, this organopolysiloxane is also capable of hydrophobizing the surface of a powder.

In the above formula (3), R⁴ represents an alkyl group having 1 to 6 carbon atoms, examples of which include alkyl groups each having 1 to 6 carbon atoms, such as a methyl group, an ethyl group and a propyl group, where a methyl group and an ethyl group are particularly preferred. Each R⁵ independently represents a saturated or unsaturated, substituted or unsubstituted monovalent hydrocarbon group having 1 to 18, preferably 1 to 10 carbon atoms. Examples of such monovalent hydrocarbon group include alkyl groups such as a methyl group, an ethyl group, a propyl group, a hexyl group, an octyl group, a decyl group, a dodecyl group, a tetradecyl group, a hexadecyl group and an octadecyl group; cycloalkyl groups such as a cyclopentyl group and a cyclohexyl group; alkenyl groups such as a vinyl group and an allyl group; aryl groups such as a phenyl group and a tolyl group; aralkyl groups such as 2-phenylethyl group and 2-methyl-2-phenylethyl group; or groups obtained by substituting a part of or all the hydrogen atoms in any of the above groups with, for example, a cyano group(s) and/or halogen atoms such as fluorine atoms, bromine atoms and chlorine atoms, examples of such substituted groups including 3,3,3-trifluoropropyl group, 2-(perfluorobutyl)ethyl group, 2-(perfluorooctyl)ethyl group and p-chlorophenyl group. Among the above examples, a methyl group is particularly preferred. In the formula (3), c represents an integer of 5 to 120, preferably an integer of 10 to 90.

### Component (B):

A component (B) is a silver powder having a tap density of not lower than 3.0 g/cm³, and a specific surface area of not larger than 2.0 m²/g.

When the tap density of the silver powder as the component (B) is lower than 3.0 g/cm³, a filling rate of the component (B) in the composition cannot be raised, which causes the viscosity of the composition to increase, and the workability thereof to thus be impaired. Therefore, the tap density of such silver powder is preferably within a range of 3.0 to 10.0 g/cm³, more preferably 4.5 to 10.0 g/cm³, and even more preferably 6.0 to 10.0 g/cm³.

When the specific surface area of the silver powder as the component (B) is larger than 2.0 m²/g, a filling rate of the component (B) in the composition cannot be raised, which causes the viscosity of the composition to increase, and the workability thereof to thus be impaired. Therefore, the specific surface area of such silver powder is preferably within a range of 0.08 to 2.0 m²/g, more preferably 0.08 to 1.0 m²/g, and even more preferably 0.08 to 0.5 m²/g.

Here, the “tap density” described in this specification is calculated as follows. That is, 100 g of the silver powder is weighed out at first, followed by gently dropping the same into a 100 ml measuring cylinder, and then placing such measuring cylinder on a tap density measuring device so as to drop the silver powder 600 times at a dropping distance of 20 mm and a rate of 60 times/min. The tap density is thus a value calculated based on the volume of such compressed silver powder.

Further, with regard to the “specific surface area,” about 2 g of the silver powder is at first taken as a sample, followed by degassing the same at 60±5° C. for 10 min, and then measuring a total surface area thereof with an automatic surface area measuring device (BET method). Later, the amount of the sample is measured, and the specific surface area is then calculated using the following formula (4).

Specific surface area(m²/g)=Total surface area(m²)/Sample amount(g) (4)

An aspect ratio of the silver powder as the component (B) is 2.0 to 150.0, preferably 3.0 to 100.0, more preferably 3.0 to 50.0. The aspect ratio refers to a ratio between a major axis and a minor axis of a particle (major axis/minor axis). A method for measuring the aspect ratio is such that, for example, an electron micrograph of particles is taken at first, followed by measuring the major and minor axes of the particles based on such electron micrograph, and then calculating the aspect ratio based on these major and minor axes of the particles that have been measured. The size of the particles can be measured based on an electron micrograph taken from above, and a larger diameter in such electron micrograph taken from above is measured as a major axis. With respect to such major axis, a minor axis thus corresponds to the thickness of a particle. The thickness of a particle cannot be measured based on an electron micrograph taken from above. The thickness of a particle may be measured as follows. That is, when taking an electron micrograph, a sample stage on which the particles have been mounted is tilted, followed by taking the electron micrograph from above, and then performing correction based on the tilt angle of the sample stage so as to calculate the particle thickness. Specifically, after taking a few electron micrographs at a magnification ratio of several thousand times, the major and minor axes of any 100 particles were measured, followed by calculating the ratios between these major and minor axes (major axis/minor axis), and then obtaining an average value thereof.

Although there are no particular restrictions on the particle size of the silver powder as the component (B), it is preferred that an average particle size thereof be 0.2 to 50 μm, particularly preferably 1.0 to 30 μm. The “average particle size” refers to a volume average diameter [MV] on volumetric basis that can be measured by a laser diffraction-type particle size analyzer as follows. That is, before measurement, the silver powder is at first taken by one to two scoops with a microspatula and put into a 100 ml beaker, followed by putting about 60 ml of isopropyl alcohol thereinto, and then using an ultrasonic homogenizer to disperse the silver powder for a minute. Here, a measurement time was 30 seconds.

Although there are no particular restrictions on a method for producing the silver powder used in the present invention, examples of such method include an electrolytic method, a crushing method, a heat treatment method, an atomizing method and a reduction method.

The silver powder produced via the above method(s) may be used as it is; or crushed before use, provided that the particle size thereof is within the aforementioned numerical value ranges. If crushing the silver powder, there are no particular restrictions on a device for crushing the same. Examples of such device include known devices such as a stamp mill, a ball mill, a vibrating mill, a hammer mill, a rolling roller and a mortar. Preferred are a stamp mill, a ball mill, a vibrating mill and a hammer mill.

The silver powder as the component (B) is in an amount of 300 to 11,000 parts by mass per 100 parts by mass of the component (A). When the component (B) is in an amount of smaller than 300 parts by mass per 100 parts by mass of the component (A), the composition obtained will exhibit an impaired thermal conductivity; when the component (B) is in an amount of larger than 11,000 parts by mass per 100 parts by mass of the component (A), the composition will exhibit an impaired fluidity and a poor workability thereby. A preferable amount of such component (B) is 300 to 5,000 parts by mass, more preferably 500 to 5,000 parts by mass.

### Component (C):

A component (C) is a thermally conductive filler other than the component (B), having an average particle size of 5 to 100 μm and a thermal conductivity of not lower than 10 W/m° C.

If the average particle size of the thermally conductive filler as the component (C) is smaller than 5 μm, the obtained composition when compressed will exhibit an extremely small minimum thickness, which leads to an impaired thermal resistance after a heat cycle test. Further, if the average particle size of the thermally conductive filler as the component (C) is larger than 100 μm, the composition obtained will exhibit a higher thermal resistance, which leads to a deterioration in the performance of the composition. Thus, it is preferred that the average particle size of the thermally conductive filler as the component (C) be 5 to 100 μm, more preferably 10 to 90 μm, and even more preferably 15 to 70 μm. Particularly, in the present invention, the average particle size of the thermally conductive filler as the component (C) refers to a volume average diameter [MV] on volumetric basis that can be measured by Microtrac MT3300EX manufactured by Nikkiso Co., Ltd.

When the thermal conductivity of the thermally conductive filler as the component (C) is lower than 10 W/m° C., the composition will exhibit a lower thermal conductivity as well. Thus, it is preferred that the thermal conductivity of the thermally conductive filler as the component (C) be not lower than 10 W/m° C., more preferably 10 to 2,000 W/m° C., even more preferably 100 to 2,000 W/m° C., and particularly preferably 200 to 2,000 W/m° C. In the present invention, the thermal conductivity of the thermally conductive filler as the component (C) refers to a value measured by QTM-500 manufactured by Kyoto Electronics Manufacturing Co., Ltd.

If the thermally conductive filler as the component (C) is added in an amount of smaller than 10 parts by mass per 100 parts by mass of the component (A), the obtained composition when compressed will exhibit an extremely small minimum thickness, which leads to an impaired thermal resistance after a heat cycle test. Further, if the thermally conductive filler as the component (C) is added in an amount of larger than 2,750 parts by mass per 100 parts by mass of the component (A), the composition obtained will exhibit an increased viscosity and a poor workability thereby. Thus, the thermally conductive filler as the component (C) is added in an amount of 10 to 2,750 parts by mass, preferably 30 to 1,000 parts by mass, more preferably 40 to 500 parts by mass.

It is preferred that the thermally conductive filler as the component (C) be an aluminum powder having a tap density of 0.5 to 2.6 g/cm³ and a specific surface area of 0.15 to 3.0 m²/g. If the tap density of the aluminum powder as the component (C) is lower than 0.5 g/cm³, the obtained composition when compressed will exhibit an extremely small minimum thickness, and the thermal resistance thereof may be impaired after a heat cycle test. Further, if such tap density is higher than 2.6 g/cm³, the composition obtained will exhibit a higher thermal resistance, which may lead to a deterioration in the performance of the composition. Thus, it is preferred that the tap density of the aluminum powder as the component (C) be 0.5 to 2.6 g/cm³, more preferably 1.0 to 2.3 g/cm³, and even more preferably 1.3 to 2.0 g/cm³. If the specific surface area of the aluminum powder as the component (C) is smaller than 0.15 m²/g, the composition obtained will exhibit a higher thermal resistance, which may lead to a deterioration in the performance of the composition. Further, if the specific surface area of the aluminum powder as the component (C) is larger than 3.0 m²/g, the obtained composition when compressed will exhibit an extremely small minimum thickness, and the thermal resistance thereof may be impaired after a heat cycle test. Thus, it is preferred that the specific surface area of the aluminum powder as the component (C) be 0.15 to 3.0 m²/g, more preferably 0.2 to 2.5 m²/g, and even more preferably 0.2 to 1.5 m²/g. Particularly, in the present invention, the tap density of the aluminum powder as the component (C) refers to a value measured by A. B. D powder tester: type A. B. D-72 manufactured by TSUTSUI SCIENTIFIC INSTRUMENTS CO., LTD. Moreover, the specific surface area of the aluminum powder as the component (C) refers to a value measured by HM model-1201 (fluidized BET method) manufactured by Mountech Co., Ltd. A method for measuring such specific surface area is a method in accordance with JIS Z 8830 2013: (ISO9277:2010).

Further, if necessary, the aluminum powder as the component (C) may be that hydrophobized with, for example, organosilane, organosilazane, organopolysiloxane or an organic fluorine compound. As a hydrophobizing method, there may be employed a known method. For example, there may be listed a method where the aluminum powder and organosilane or its partial hydrolysate are mixed together with a mixer such as Trimix, Twinmix and Planetary Mixer (all are registered trademarks of mixers by INOUE MFG., INC.); Ultramixer (registered trademark of mixer by MIZUHO INDUSTRIAL CO., LTD); and HIVIS DISPER MIX (registered trademark of mixer by PRIMIX Corporation). At that time, if necessary, the mixed ingredients may be heated to 50 to 100° C. In addition, a solvent such as toluene, xylene, petroleum ether, mineral spirit, isoparaffin, isopropyl alcohol and ethanol may be used for mixing. In such case, it is preferred that the solvent be eliminated by a vacuum device or the like after mixing. As a diluting solvent, there may also be used the organopolysiloxane as the component (A) which is a liquid component of the invention. In such case, the organopolysiloxane is mixed in advance with organosilane or its partial hydrolysate as a treating agent, followed by adding the aluminum powder thereto so as to perform hydrophobization and mixing at the same time.

A composition produced by this method is also included in the scope of the present invention.

Further, it is preferred that an aspect ratio of the thermally conductive filler as the component (C) be 1.0 to 3.0, more preferably 1.0 to 2.0, and even more preferably 1.0 to 1.5. The aspect ratio refers to a ratio between a major axis and a minor axis of a particle (major axis/minor axis). A method for measuring the aspect ratio is such that, for example, an electron micrograph of particles is taken at first, followed by measuring the major and minor axes of the particles based on such electron micrograph, and then calculating the aspect ratio based on these major and minor axes of the particles that have been measured. The size of the particles can be measured based on an electron micrograph taken from above, and a larger diameter in such electron micrograph taken from above is measured as a major axis. With respect to such major axis, a minor axis thus corresponds to the thickness of a particle. The thickness of a particle cannot be measured based on an electron micrograph taken from above. The thickness of a particle may be measured as follows. That is, when taking an electron micrograph, a sample stage on which the particles have been mounted is tilted, followed by taking the electron micrograph from above, and then performing correction based on the tilt angle of the sample stage so as to calculate the particle thickness. Specifically, after taking a few electron micrographs at a magnification ratio of several thousand times, the major and minor axes of any 100 particles were measured, followed by calculating the ratios between these major and minor axes (major axis/minor axis), and then obtaining an average value thereof.

When α/β which is a ratio of a mass α of the silver powder as the component (B) to a mass β of the aluminum powder as the component (C) is smaller than 3, the composition obtained will exhibit a decreased thermal conductivity. Further, when α/β is larger than 150, the obtained composition when compressed will exhibit an extremely small minimum thickness, and the thermal resistance thereof may be impaired after a heat cycle test. Thus, it is preferred that the mass ratio α/β be 3 to 150, more preferably 8 to 100, and even more preferably 10 to 80.

Further, the thermally conductive silicone composition of the present invention may also contain an inorganic compound powder and/or an organic compound material other than the components (B) and (C), without impairing the effects of the invention. As such inorganic compound powder, those with a high thermal conductivity are preferred, examples of which include at least one selected from an aluminum powder, a zinc oxide powder, a titanium oxide powder, a magnesium oxide powder, an alumina powder, an ammonium hydroxide powder, a boron nitride powder, an aluminum nitride powder, a diamond powder, a gold powder, a copper powder, a carbon powder, a nickel powder, an indium powder, a gallium powder, a metallic silicon powder and a silicon dioxide powder. As for the organic compound material, those with a high thermal conductivity are preferred as well, examples of which include at least one selected from a carbon fiber, graphene, graphite, a carbon nanotube and a carbon material. If necessary, these inorganic compound powder and organic compound material may be those surface-hydrophobized with organosilane, organosilazane, organopolysiloxane, an organic fluorine compound or the like. A filling rate of the inorganic compound powder and organic compound material in the composition will not increase, if the average particle size thereof is either smaller than 0.5 μm or larger than 100 μm. Thus, it is preferred that the average particle size of the inorganic compound powder and organic compound material be 0.5 to 100 μm, particularly preferably 1 to 50 μm. In addition, a filling rate of a carbon fiber the composition will not increase, if the fiber length of such carbon fiber is either smaller than 10 μm or larger than 500 μm. Thus, it is preferred that the fiber length of such carbon fiber be 10 to 500 μm, particularly preferably 30 to 300 μm. If the inorganic compound powder and organic compound material are added in an amount of larger than 3,000 parts by mass per 100 parts by mass of the component (A), the composition will exhibit an impaired fluidity and a poor workability thereby. Thus, it is preferred that the inorganic compound powder and organic compound material be added in an amount of 0 to 3,000 parts by mass, particularly preferably 0 to 2,000 parts by mass.

### Component (D):

A component (D) is a catalyst selected from the group consisting of a platinum-based catalyst, an organic peroxide and a catalyst for condensation reaction. The composition of the present invention can thus be turned into a curable composition by containing such catalyst as the component (D).

If the thermally conductive silicone composition of the invention is prepared as a composition curable via hydrosilylation reaction, the components (E) and (F) are added as the component (A), and a platinum-based catalyst is added as the component (D). It is preferred that the component (F) be added in an amount at which the silicon atom-bonded hydrogen atoms in the component (F) will be present in an amount of 0.1 to 15.0 mol, more preferably 0.1 to 10.0 mol, and particularly preferably 0.1 to 5.0 mol, per 1 mol of the alkenyl groups in the component (E).

Examples of the platinum-based catalyst as the component (D) include chloroplatinic acid, an alcohol solution of chloroplatinic acid, an olefin complex of platinum, an alkenylsiloxane complex of platinum, and carbonyl complex of platinum.

In the thermally conductive silicone composition of the present invention, the platinum-based catalyst as the component (D) is contained in an amount required to cure the composition of the invention i.e. a catalyst amount. Specifically, it is preferred that the platinum-based catalyst as the component (D) be added in an amount at which the platinum metal in the component (D) will be in an amount of 0.1 to 2,000 ppm, particularly preferably 0.1 to 1,500 ppm, in mass unit with respect to the component (A).

Further, in order to control the curing rate of the thermally conductive silicone composition of the invention and thus improve the workability thereof, the composition of the invention may also contain a curing reaction inhibitor such as: an acetylene-based compound, e.g. 2-methyl-3-butyne-2-ol, 2-phenyl-3-butyne-2-ol and 1-ethynyl-1-cyclohexanol; an ene-yne compound, e.g. 3-methyl-3-pentene-1-yne and 3,5-dimethyl-3-hexene-1-yne; a hydrazine-based compound; a phosphine-based compound; and a mercaptan-based compound. Although there are no particular restrictions on the amount of such curing reaction inhibitor contained, it is preferred that this curing reaction inhibitor be added in an amount of 0.0001 to 1.0 parts by mass per 100 parts by mass of the component (A).

However, if the thermally conductive silicone composition of the invention is prepared as a composition curable via free radical reaction caused by an organic peroxide, it is preferred that an organic peroxide be used as the component (D). Examples of the organic peroxide as the component (D) include benzoyl peroxide, di(p-methylbenzoyl)peroxide, di(o-methylbenzoyl)peroxide, dicumyl peroxide, 2,5-dimethyl-2,5-bis(t-butylperoxy)hexane, di-t-butyl peroxide, t-butylperoxy benzoate and 1,1-di(t-butylperoxy)cyclohexane. The organic peroxide as the component (D) is contained in an amount required to cure the composition of the invention. Specifically, it is preferred that the organic peroxide as the component (D) be contained in an amount of 0.1 to 8 parts by mass per 100 parts by mass of the component (A).

Further, if the thermally conductive silicone composition of the invention is prepared as a composition curable via condensation reaction, it is preferred that the composition of the invention contain as a curing agent, a silane or siloxane oligomer having at least three silicon atom-bonded hydrolyzable groups in one molecule; and as the component (D), a catalyst for condensation reaction. Here, examples of such silicon atom-bonded hydrolyzable group include an alkoxy group, an alkoxyalkoxy group, an acyloxy group, a ketoxime group, an alkenoxy group, an amino group, an aminoxy group and an amide group. Moreover, other than the abovementioned hydrolyzable groups, a linear alkyl group, a branched alkyl group, a cyclic alkyl group, an alkenyl group, an aryl group, an aralkyl group, a halogenated alkyl group or the like may be bonded to the silicon atoms in the above silane or siloxane oligomer. Examples of such silane or siloxane oligomer include tetraethoxysilane, methyltriethoxysilane, vinyltriethoxysilane, methyltris(methylethylketoxime)silane, vinyltriacetoxysilane, ethyl orthosilicate and vinyltri(isopropenoxy)silane.

This silane or siloxane oligomer is contained in an amount required to cure the composition of the invention. Specifically, this silane or siloxane oligomer is added in an amount of 0.01 to 20 parts by mass, particularly preferably 0.1 to 10 parts by mass, per 100 parts by mass of the component (A).

In addition, the catalyst for condensation reaction, as the component (D), is an optional component; and is thus not essential if employing, as a curing agent, a silane having a hydrolyzable group(s) such as an aminoxy group, an amino group and a ketoxime group. Examples of the catalyst for condensation reaction, as the component (D), include: organic titanate esters such as tetrabutyl titanate and tetraisopropyl titanate; organic titanium chelate compounds such as diisopropoxybis(acetylacetate)titanium and diisopropoxybis(ethylacetoacetate)titanium; organic aluminum compounds such as aluminum tris(acetylacetonate) and aluminum tris(ethylacetoacetate); organic zirconium compounds such as zirconium tetra(acetylacetonate) and zirconium tetrabutylate; organic tin compounds such as dibutyl tin dioctoate, dibutyl tin dilaurate and butyl tin-2-ethylhexoate; metallic salts of organic carboxylic acids, such as tin naphthenate, tin oleate, tin butyrate, cobalt naphthenate and zinc stearate; amine compounds such as hexylamine and dodecylamine phosphate, and the salts thereof; quaternary ammonium salts such as benzyltriethylammonium acetate; lower fatty acid salts of alkali metals, such as potassium acetate; dialkylhydroxylamines such as dimethylhydroxylamine and diethylhydroxylamine; and guanidyl group-containing organic silicon compounds.

In the thermally conductive silicone composition of the invention, the contained amount of the catalyst for condensation reaction, as the component (D), is an arbitrary amount. Specifically, if added, it is preferred that the catalyst for condensation reaction, as the component (D), be added in an amount of 0.01 to 20 parts by mass, particularly preferably 0.1 to 10 parts by mass, per 100 parts by mass of the component (A).

### Component (G):

In addition, as a component (G), there may also be added to the thermally conductive silicone composition of the invention an organosilane represented by the following general formula (2):

R²_{b}Si(OR³)_{4-b} (2)

(In the above formula, R² represents at least one group selected from: a saturated or unsaturated monovalent hydrocarbon group that may have a substituent group(s); an epoxy group; an acrylic group; and a methacrylic group. R³ represents a monovalent hydrocarbon group. b satisfies 1≤b≤3.)

Examples of R² in the general formula (2) include alkyl groups such as a methyl group, an ethyl group, a propyl group, a hexyl group, an octyl group, a nonyl group, a decyl group, a dodecyl group and a tetradecyl group; a cycloalkylalkenyl group; an acrylic group; an epoxy group; cycloalkyl groups such as a cyclopentyl group and a cyclohexyl group; alkenyl groups such as a vinyl group and an allyl group; aryl groups such as a phenyl group and a tolyl group; aralkyl groups such as 2-phenylethyl group and 2-methyl-2-phenylethyl group; and halogenated hydrocarbon groups such as 3,3,3-trifluoropropyl group, 2-(perfluorobutyl)ethyl group, 2-(perfluorooctyl)ethyl group and p-chlorophenyl group. Examples of the substituent group(s) in the monovalent hydrocarbon group include an acryloyloxy group and a methacryloyloxy group. Further, b represents 1 to 3. Examples of R³ include at least one alkyl group having 1 to 6 carbon atoms, such as a methyl group, an ethyl group, a propyl group, a butyl group, a pentyl group and a hexyl group, among which a methyl group and an ethyl group are particularly preferred.

Following are examples of the organosilane as the component (G) and as represented by the general formula (2).

C₁₀H₂₁Si(OCH₃)₃

C₁₂H₂₅Si(OCH₃)₃

C₁₂H₂₅Si(OC₂H₅)₃

C₁₀H₂₁Si(CH₃)(OCH₃)₂

C₁₀H₂₁Si(C₆H₆)(OCH₃)₂

C₁₀H₂₁Si(CH₃)(OC₂H₅)₂

C₁₀H₂₁Si(CH═CH₂)(OCH₃)₂

C₁₀H₂₁Si(CH₂CH₂CF₃)(OCH₃)₂

CH₂═C(CH₃)COOC₈H₁₆Si(OCH₃)₃

If adding the organosilane as the component (G), it is preferred that it be added in an amount of 0.1 to 20 parts by mass, more preferably 0.1 to 10 parts by mass, per 100 parts by mass of the component (A).

As a method for producing the thermally conductive silicone composition of the invention, there may be employed a conventional method for producing a silicone composition, and there are no particular restrictions on such method. For example, the composition of the invention can be produced by mixing the components (A) to (D) and other components if necessary, for 30 min to 4 hours, using a mixer such as Trimix, Twinmix and Planetary Mixer (all are registered trademarks of mixers by INOUE MFG., INC.); Ultramixer (registered trademark of mixer by MIZUHO INDUSTRIAL CO., LTD); and HIVIS DISPER MIX (registered trademark of mixer by PRIMIX Corporation). Further, if required, mixing may be performed while heating the components to a temperature of 50 to 150° C.

It is preferred that the absolute viscosity of the thermally conductive silicone composition of the invention that is measured at 25° C. be 10 to 600 Pa·s, more preferably 15 to 500 Pa·s, and even more preferably 15 to 400 Pa·s. When the absolute viscosity is within these ranges, there can be provided a favorable grease, and a superior workability can thus be achieved as well. The absolute viscosities within the above ranges can be achieved by adjusting the amount of each component added. The aforementioned viscosity was measured by PC-1TL (10 rpm) manufactured by Malcom Co., Ltd.

Although there are no restrictions on the property of a thermally conductive silicone cured product obtained by curing the thermally conductive silicone composition of the invention, the cured product may be in the form of, for example, a gel, a low hardness rubber or a high hardness rubber.

### Semiconductor Device:

A semiconductor device of the present invention is characterized by having the thermally conductive silicone composition of the invention interposed between a heat-generating electronic part and a heat dissipator. It is preferred that the thermally conductive silicone composition of the invention be interposed between the heat-generating electronic part and the heat dissipator by a thickness of 10 to 200 μm.

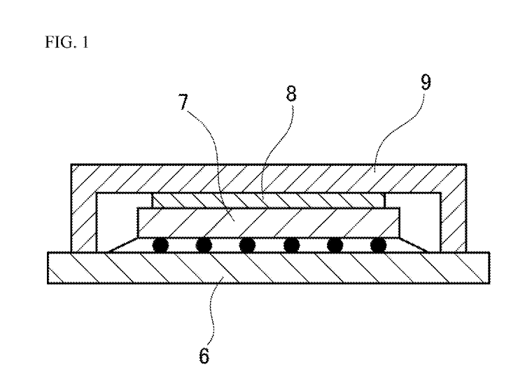

A typical structure of the semiconductor device of the invention is shown in FIG. 1. However, the present invention is not limited to this structure. The thermally conductive silicone composition of the invention is represented by “8” in FIG. 1.

In order to produce the semiconductor device of the invention, preferred is a method in which the thermally conductive silicone composition of the invention sandwiched between the heat-generating electronic part and the heat dissipator is heated to 80° C. or higher with a pressure of not lower than 0.01 MPa being applied thereto. At that time, it is preferred that the pressure applied thereto be not lower than 0.01 MPa, more preferably 0.05 to 100 MPa, and even more preferably 0.1 to 100 MPa. The heating temperature needs to be 80° C. or higher. It is preferred that the heating temperature be 90 to 300° C., more preferably 100 to 300° C., and even more preferably 120 to 300° C.

### Working Example

The present invention is described in greater detail hereunder with reference to working and comparative examples for the purpose of further clarifying the effects of the invention. However, the present invention is not limited to these examples.

Tests for confirming the effects of the present invention were performed as follows.

### Viscosity

The absolute viscosity of the composition was measured by a Malcolm viscometer (type: PC-1TL) at 25° C.

### Thermal Conductivity

In working examples 1 to 14; and comparative examples 1 to 8, each composition was poured into a mold having a thickness of 6 mm, followed by heating the composition to 150° C. with a pressure of 0.35 MPa being applied thereto, and then using TPS-2500S manufactured by Kyoto Electronics Manufacturing Co., Ltd. to measure the thermal conductivity thereof at 25° C. In working example 15, the composition was poured into a mold having a thickness of 6 mm, and then left for seven days under a condition of 23±2° C./50±5% RH (relative humidity). TPS-2500S manufactured by Kyoto Electronics Manufacturing Co., Ltd. was later used to measure the thermal conductivity of the composition at 25° C.

### Thermal Resistance Measurement

Each composition was sandwiched between two aluminum plates each being formed into a size of φ (diameter) 12.7 mm, followed by leaving them in an oven of 150° C. for 90 min with a pressure of 0.35 MPa being applied thereto. In this way, each composition was able to be heated and cured, and a test specimen for thermal resistance measurement was thus obtained. The thermal resistance of such test specimen was then measured. In addition, a heat cycle test (−55° C.↔150° C.) was later performed for 1,000 hours to observe changes in thermal resistance. Here, this thermal resistance measurement was carried out using NanoFlash (LFA447 by NETZSCH).

Measurement of Minimum Thickness when Compressed (BLT)

The thickness of two aluminum plates each being formed into a size of φ 12.7 mm were measured, followed by sandwiching each composition between the two aluminum plates whose total thickness had been measured, and then leaving them in an oven of 150° C. for 90 min with a pressure of 0.35 MPa being applied thereto. A test specimen for BLT measurement was thus obtained, and the thickness of such test specimen was then measured. Further, BLT was calculated using the following formula (5).

BLT(μm)=thickness of test specimen(μm)−thickness of two aluminum plates used(μm) (5)

Here, the thickness of the test specimen was measured by a Digimatic Standard Outside Micrometer (MDC-25MX by Mitutoyo Corporation).

The following components were prepared for producing the composition of the invention.

### Component (A)

A-1: Dimethylpolysiloxane with both terminals blocked by dimethylvinylsilyl group, and exhibiting a kinetic viscosity of 600 mm²/s at 25° C.

A-2: Organohydrogenpolysiloxane represented by the following formula:

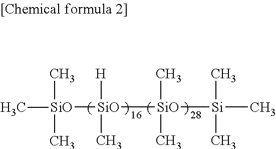

A-3: Dimethylpolysiloxane with both terminals blocked by hydroxyl group, and exhibiting a kinetic viscosity of 5,000 mm²/s at 25° C.

### Component (B)

B-1: Silver powder having a tap density of 6.6 g/cm³, a specific surface area of 0.28 m²/g, and an aspect ratio of 8

B-2: Silver powder having a tap density of 6.2 g/cm³, a specific surface area of 0.48 m²/g, and an aspect ratio of 13

B-3: Silver powder having a tap density of 9.0 g/cm³, a specific surface area of 0.16 m²/g, and an aspect ratio of 30

B-4: Silver powder having a tap density of 3.0 g/cm³, a specific surface area of 2.0 m²/g, and an aspect ratio of 50

B-5 (comparative example): Silver powder having a tap density of 2.3 g/cm³, a specific surface area of 2.3 m²/g, and an aspect ratio of 1

B-6 (comparative example): Silver powder having a tap density of 3.3 g/cm³, a specific surface area of 2.11 m²/g, and an aspect ratio of 1

B-7 (comparative example): Silver powder having a tap density of 2.8 g/cm³, a specific surface area of 1.8 m²/g, and an aspect ratio of 2

### Component (C)

C-1: Aluminum powder having an average particle size of 15 μm, a thermal conductivity of 230 W/m° C., a tap density of 1.3 g/cm³, a specific surface area of 1.5 m²/g, and an aspect ratio of 1.5

C-2: Aluminum powder having an average particle size of 20 μm, a thermal conductivity of 230 W/m° C., a tap density of 1.5 g/cm³, a specific surface area of 0.3 m²/g, and an aspect ratio of 1.2

C-3: Aluminum powder having an average particle size of 70 μm, a thermal conductivity of 230 W/m° C., a tap density of 2.0 g/cm³, a specific surface area of 0.2 m²/g, and an aspect ratio of 1.1

C-4: Silver powder having an average particle size of 11 μm, a thermal conductivity of 400 W/m° C., a tap density of 5.2 g/cm³, a specific surface area of 0.2 m²/g, and an aspect ratio of 1.1

C-5 (comparative example): Aluminum powder having an average particle size of 110 μm, a thermal conductivity of 230 W/m° C., a tap density of 2.0 g/cm³, a specific surface area of 0.12 m²/g, and an aspect ratio of 1.1

### Component (D)

D-1 (Platinum catalyst): A-1 solution of platinum-divinyltetramethyldisiloxane complex, contained in an amount of 1 wt % in terms of platinum atoms

D-2 (Organic peroxide): Peroxide (product name: PERHEXA C by NOF CORPORATION)

D-3 (Catalyst for condensation reaction): Tetramethylguanidylpropyltrimethoxysilane

### Component (G)

G-1: Organosilane represented by the following formula:

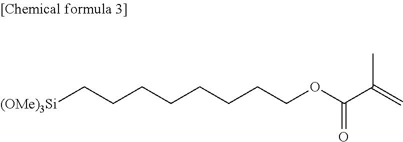

### Component (H)

H-1: Organopolysiloxane represented by the following formula:

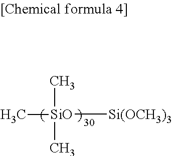

### Component (I)

I-1 (Curing reaction inhibitor): 1-ethynyl-1-cyclohexanol

### Component (J)

J-1 (Curing agent): Vinyltri(isopropenoxy)silane

### Working Examples 1 to 15; and Comparative Examples 1 to 8

The above components were mixed at the compounding ratios shown in the following Tables 1 to 3, and each composition in working examples 1 to 15 and comparative examples 1 to 8 was thus obtained.

Specifically, the component (A) was put into a planetary mixer (by INOUE MFG., INC.) having a volume of 5 L, followed by adding thereto the component (G) in the case of working example 4 or the component (H) in the case of working example 5. The components (B) and (C) were further added thereto, followed by performing mixing at 25° C. for 1.5 hours. Next, the component (D) was added; and the component (I) in the cases of working examples 1 to 8 and comparative examples 1 to 8 or the component (J) in the case of working example 15 was further added, followed by performing mixing so as to homogenize the components added.

TABLE 1
Unit: part by mass

| | Working example | | | | | | | |
|---|---|---|---|---|---|---|---|---|
| | 1 | 2 | 3 | 4 | 5 | 6 | 7 | 8 |
| A-1 | 95 | 95 | 95 | 95 | 95 | 95 | 95 | 95 |
| A-2 | 5 | 5 | 5 | 5 | 5 | 5 | 5 | 5 |
| A-3 | | | | | | | | |
| B-1 | 600 | 4800 | 4800 | 4800 | 4800 | 950 | 950 | 950 |
| B-2 | | | | | | | | |
| B-3 | | | | | | | | |
| B-4 | | | | | | | | |
| B-5 | | | | | | | | |
| B-6 | | | | | | | | |
| B-7 | | | | | | | | |
| C-1 | 40 | 40 | 500 | 500 | 500 | | | |
| C-2 | | | | | | 60 | | |
| C-3 | | | | | | | 60 | |
| C-4 | | | | | | | | 60 |
| C-5 | | | | | | | | |
| D-1 | 6.73 | 6.73 | 6.73 | 6.73 | 6.73 | 6.73 | 6.73 | 6.73 |
| D-2 | | | | | | | | |
| D-3 | | | | | | | | |
| G-1 | | | | 10 | | | | |
| H-1 | | | | | 10 | | | |
| I-1 | 0.17 | 0.17 | 0.17 | 0.17 | 0.17 | 0.17 | 0.17 | 0.17 |
| J-1 | | | | | | | | |
| Viscosity | 15 | 355 | 399 | 380 | 375 | 20 | 121 | 23 |
| (Pa · s) | | | | | | | | |
| Thermal | 17 | 85 | 91 | 85 | 83 | 20 | 20 | 27 |
| conductivity | | | | | | | | |
| (W/mK) | | | | | | | | |
| BLT (μm) | 20 | 18 | 23 | 23 | 23 | 23 | 80 | 15 |
| Thermal | 6.5 | 1.7 | 1.9 | 2.2 | 2.4 | 4.1 | 8.0 | 3.5 |
| resistance | | | | | | | | |
| (mm² · K/W) | | | | | | | | |
| Thermal resistance | 6.6 | 2.4 | 2.3 | 2.5 | 2.5 | 4.1 | 8.2 | 3.6 |
| after heat cycle test | | | | | | | | |
| (mm² · K/W) | | | | | | | | |

TABLE 2
Unit: part by mass

| | Working example | | | | | | |
|---|---|---|---|---|---|---|---|
| | 9 | 10 | 11 | 12 | 13 | 14 | 15 |
| A-1 | 95 | 95 | 95 | 95 | 95 | 95 | |
| A-2 | 5 | 5 | 5 | 5 | 5 | 5 | |
| A-3 | | | | | | | 100 |
| B-1 | 950 | | | | | | 950 |
| B-2 | | 950 | | | 11,000 | 11,000 | |
| B-3 | | | 950 | | | | |
| B-4 | | | | 950 | | | |
| B-5 | | | | | | | |
| B-6 | | | | | | | |
| B-7 | | | | | | | |
| C-1 | | | | | | | |
| C-2 | 60 | 60 | 60 | 60 | 60 | 2,750 | 60 |
| C-3 | | | | | | | |
| C-4 | | | | | | | |
| C-5 | | | | | | | |
| D-1 | | | | | | | |
| D-2 | 6 | 6 | 6 | 6 | 6 | 6 | |
| D-3 | | | | | | | 7 |
| G-1 | | | | | | | |
| H-1 | | | | | | | |
| I-1 | | | | | | | |
| J-1 | | | | | | | 1 |
| Viscosity | 20 | 40 | 15 | 100 | 575 | 599 | 30 |
| (Pa · s) | | | | | | | |
| Thermal | 20 | 23 | 27 | 20 | 92 | 95 | 27 |
| conductivity | | | | | | | |
| (W/mK) | | | | | | | |
| BLT (μm) | 23 | 23 | 23 | 23 | 20 | 23 | 23 |
| Thermal | 4.1 | 4.3 | 3.5 | 5.5 | 1.4 | 1.4 | 4.5 |
| resistance | | | | | | | |
| (mm² · K/W) | | | | | | | |
| Thermal | 4.1 | 4.4 | 3.6 | 5.6 | 2.0 | 1.6 | 4.8 |
| resistance | | | | | | | |
| after heat | | | | | | | |
| cycle test | | | | | | | |
| (mm² · K/W) | | | | | | | |

TABLE 3
Unit: part by mass

| | Comparative example | | | | | | | |
|---|---|---|---|---|---|---|---|---|
| | 1 | 2 | 3 | 4 | 5 | 6 | 7 | 8 |
| A-1 | 95 | 95 | 95 | 95 | 95 | 95 | 95 | 95 |
| A-2 | 5 | 5 | 5 | 5 | 5 | 5 | 5 | 5 |
| A-3 | | | | | | | | |
| B-1 | 280 | 12,000 | 950 | 950 | | | | |
| B-2 | | | | | | | | |
| B-3 | | | | | 950 | | | |
| B-4 | | | | | | | | |
| B-5 | | | | | | 950 | | |
| B-6 | | | | | | | 950 | |
| B-7 | | | | | | | | 950 |
| C-1 | 40 | 40 | | | | | | |
| C-2 | | | | 1 | 3000 | 60 | 60 | 60 |
| C-3 | | | | | | | | |
| C-4 | | | | | | | | |
| C-5 | | | 60 | | | | | |
| D-1 | 6.73 | 6.73 | 6.73 | 6.73 | 6.73 | 6.73 | 6.73 | 6.73 |
| D-2 | | | | | | | | |
| D-3 | | | | | | | | |
| G-1 | | | | | | | | |
| H-1 | | | | | | | | |
| I-1 | 0.17 | 0.17 | 0.17 | 0.17 | 0.17 | 0.17 | 0.17 | 0.17 |
| J-1 | | | | | | | | |
| Viscosity | 10 | Failed to | 20 | 18 | 200 | 677 | 655 | 665 |
| (Pa · s) | | form | | | | | | |
| Thermal | 2 | grease | 18 | 19 | 6 | 5 | 6 | 6 |
| conductivity | | | | | | | | |
| (W/mK) | | | | | | | | |
| BLT (μm) | 20 | | 130 | 6 | 23 | 21 | 22 | 22 |
| Thermal | 15.3 | | 18.5 | 4.5 | 13.2 | 14.2 | 14.0 | 14.7 |
| resistance | | | | | | | | |
| (mm² · K/W) | | | | | | | | |
| Thermal resistance | 15.6 | | 18.5 | 16.7 | 13.3 | 14.8 | 15.0 | 15.0 |
| after heat cycle test | | | | | | | | |
| (mm² · K/W) | | | | | | | | |

### DESCRIPTION OF THE SYMBOLS

6 Substrate
7 Heat-generating electronic part (CPU)
8 Thermally conductive silicone composition layer
9 Heat dissipator (Lid)

1. A thermally conductive silicone composition comprising:
(A) an organopolysiloxane that exhibits a kinetic viscosity of 10 to 100,000 mm²/s at 25° C., and is represented by the following average composition formula (1)
R¹ₐSiO_{(4-a)/2} (1)
wherein R¹ represents at least one selected from the group consisting of a hydrogen atom, a hydroxy group and a saturated or unsaturated monovalent hydrocarbon group having 1 to 18 carbon atoms, and a satisfies 1.8≤a≤2.2;
(B) a silver powder having a tap density of not lower than 3.0 g/cm³, a specific surface area of not larger than 2.0 m²/g, and an aspect ratio of 2.0 to 150.0, the component (B) being in an amount of 300 to 11,000 parts by mass per 100 parts by mass of the component (A);
(C) a thermally conductive filler other than the component (B), having an average particle size of 5 to 100 μm and a thermal conductivity of not lower than 10 W/m° C., the component (C) being in an amount of 10 to 2,750 parts by mass per 100 parts by mass of the component (A); and
(D) a catalyst selected from the group consisting of a platinum-based catalyst, an organic peroxide and a catalyst for condensation reaction, the component (D) being used in a catalyst amount.

2. The thermally conductive silicone composition according to claim 1, wherein the thermally conductive filler as the component (C) is an aluminum powder having a tap density of 0.5 to 2.6 g/cm³ and a specific surface area of 0.15 to 3.0 m²/g.

3. The thermally conductive silicone composition according to claim 1, wherein the thermally conductive filler as the component (C) has an aspect ratio of 1.0 to 3.0.

4. The thermally conductive silicone composition according to claim 1, wherein α/β which is a ratio of a mass α of the silver powder as the component (B) to a mass β of the aluminum powder as the component (C) is 3 to 150.

5. The thermally conductive silicone composition according to claim 1, wherein the whole or part of the component (A) is: an organopolysiloxane as a component (E) that has at least two silicon atom-bonded alkenyl groups in one molecule; and/or an organohydrogenpolysiloxane as a component (F) that has at least two silicon atom-bonded hydrogen atoms in one molecule.

6. The thermally conductive silicone composition according to claim 1, further comprising:
(G) an organosilane that is contained in an amount of 0 to 20 parts by mass per 100 parts by mass of the component (A), and is represented by the following general formula (2)
R²_{b}Si(OR³)_{4-b} (2)
wherein R² represents at least one group selected from: a saturated or unsaturated monovalent hydrocarbon group that may have a substituent group(s); an epoxy group; an acrylic group; and a methacrylic group, R³ represents a monovalent hydrocarbon group, and b satisfies 1≤b≤3.

7. A semiconductor device comprising a heat-generating electronic part and a heat dissipator with the thermally conductive silicone composition as set forth in claim 1 being interposed between the heat-generating electronic part and the heat dissipator.

8. A method for producing a semiconductor device, comprising:
heating the thermally conductive silicone composition as set forth in claim 1 to 80° C. or higher with a pressure of not lower than 0.01 MPa being applied thereto, with the thermally conductive silicone composition being sandwiched between a heat-generating electronic part and a heat dissipator.
